(19) United States
(12) Patent Application Publication
(10) Pub. No.: US 2023/0411383 A1
(43) Pub. Date: Dec. 21, 2023

(54) ELECTROSTATIC PROTECTION CIRCUIT AND SEMICONDUCTOR CHIP

(71) Applicant: Changxin Memory Technologies, Inc., Hefei City (CN)

(72) Inventor: Qian Xu, Hefei (CN)

(21) Appl. No.: 18/150,862

(22) Filed: Jan. 6, 2023

Related U.S. Application Data
(63) Continuation of application No. PCT/CN2022/105165, filed on Jul. 12, 2022.

(30) Foreign Application Priority Data
Jun. 17, 2022 (CN) 202210691753.6

(51) Int. Cl. H01L 27/02

(52) U.S. Cl. CPC H01L 27/0285

(57) ABSTRACT

An electrostatic protection circuit and a semiconductor chip are provided. The electrostatic protection circuit is connected to first and second voltage ends. The electrostatic protection circuit includes: a first detection circuit, a control circuit and a discharge transistor. The first detection circuit outputs a first detection signal to the control circuit within a first preset duration after an electrostatic charge appears on the first voltage end; and the control circuit drives the discharge transistor to discharge electrostatic charges under the control of the first detection signal. The electrostatic protection circuit further includes a shutdown circuit. The output end of the shutdown circuit is connected to a control end of the discharge transistor, which is used to output a control signal after a second preset duration after the electrostatic charge appears to shut down the discharge transistor. The second preset duration is greater than or equal to the first preset duration.

### CROSS-REFERENCE TO RELATED APPLICATION

The present disclosure is a continuation of International Application No. PCT/CN2022/105165, filed on Jul. 12, 2022, which claims priority to Chinese Patent Application No. 202210691753.6, filed on Jun. 17, 2022 and entitled “ELECTROSTATIC PROTECTION CIRCUIT AND SEMICONDUCTOR CHIP”. The disclosures of International Application No. PCT/CN2022/105165 and Chinese Patent Application No. 202210691753.6 are hereby incorporated by reference in their entireties.

### BACKGROUND

For semiconductor devices, static electricity is one of unavoidable phenomena. In order to reduce an impact of static electricity on devices, it is necessary to design effective Electro-Static discharge (ESD) protection circuits in the manufacturing process of semiconductor devices. However, with the continuous development of large-scale integrated circuits, the demand for high integration is constantly rising. Since devices become more and more sophisticated, it brings great challenges to the design of electrostatic protection circuits.

### SUMMARY

Embodiments of the present disclosure relate to the field of semiconductor technologies, and relate to, but are not limited to, an electrostatic protection circuit and a semiconductor chip.

In view of this, the embodiments of the present disclosure provide an electrostatic protection circuit and a semiconductor chip.

In a first aspect, an embodiment of the present disclosure provides an electrostatic protection circuit which is connected to a first voltage end and a second voltage end, and the electrostatic protection circuit includes a first detection circuit, a control circuit and a discharge transistor.

The first detection circuit is connected between the first voltage end and the second voltage end, where the first detection circuit is configured to: output a first detection signal within a first preset duration after an electrostatic charge appears on the first voltage end, or output a second detection signal after the first preset duration after the electrostatic charge appears on the first voltage end.

The control circuit is connected between the first voltage end and the second voltage end, where an input end of the control circuit is connected to an output end of the first detection circuit; and the control circuit is configured to: output a first level in a state that the first detection signal is received, or output a second level in a state that the second detection signal is received.

The discharge transistor is connected between the first voltage end and the second voltage end, where a control end of the discharge transistor is connected to an output end of the control circuit; the discharge transistor is configured to be switched to a turn-on state when the control end of the discharge transistor is at the first level, so as to discharge the electrostatic charges to the second voltage end; and the discharge transistor is further configured to be switched to a turn-off state when the control end of the discharge transistor is at the second level.

The shutdown circuit is connected between the first voltage end and the second voltage end, where an output end of the shutdown circuit is connected to the control end of the discharge transistor; the shutdown circuit is configured to output a control signal after a second preset duration after the electrostatic charge appears on the first voltage end; and the control signal is used to turn off the discharge transistor.

The second preset duration is greater than or equal to the first preset duration.

In a second aspect, an embodiment of the present disclosure provides a semiconductor chip, which includes a first voltage end, a second voltage end and the electrostatic protection circuit according to any one of the above embodiments.

### BRIEF DESCRIPTION OF THE DRAWINGS

FIG. 1 is a structural schematic diagram of an electrostatic protection circuit according to an example;

FIG. 2 is a structural schematic diagram of an electrostatic protection circuit according to another example;

FIG. 3 is a structural schematic diagram of an electrostatic protection circuit according to an embodiment of the present disclosure;

FIG. 4 is a structural schematic diagram of another electrostatic protection circuit according to an embodiment of the present disclosure;

FIG. 5 is a structural schematic diagram of still another electrostatic protection circuit according to an embodiment of the present disclosure;

FIG. 6 is a structural schematic diagram of still another electrostatic protection circuit according to an embodiment of the present disclosure;

FIG. 7 is a structural schematic diagram of still another electrostatic protection circuit according to an embodiment of the present disclosure; and

FIG. 8 is a structural schematic diagram of a semiconductor chip according to an embodiment of the present disclosure.

### DETAILED DESCRIPTION

In order to facilitate the understanding of the present disclosure, a more comprehensive description of the present disclosure will be given below with reference to the relevant accompanying drawings. Preferred embodiments of the present disclosure are given in the accompanying drawings. However, the present disclosure may be implemented in many different forms, and is not limited to the embodiments described herein. In contrast, the purpose of providing these embodiments is to make the disclosure of the present disclosure more thorough and comprehensive.

Unless otherwise defined, all technical and scientific terms used herein have the same meanings as those commonly understood by those skilled in the art of the present disclosure. The terms used in the specification of the present disclosure herein are only for the purpose of describing specific embodiments, and are not intended to limit the present disclosure. The term “and/or” as used herein includes any and all combinations of one or more related listed items.

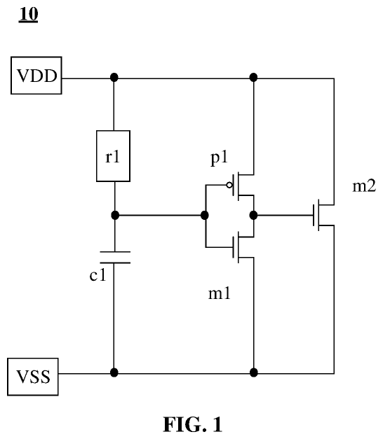

For the electrostatic protection of full chip integrated circuits, electrostatic protection circuits are usually required to be established between power supplies. In some examples, an electrostatic protection circuit 10 as shown in FIG. 1 may be employed. The electrostatic protection circuit 10 shown in FIG. 1 includes a detection circuit, a control circuit and a discharge transistor. The detection circuit includes a resistor r1 and a capacitor c1. The control circuit includes a transistor p1 and a transistor m1. The discharge transistor m2 may be an NMOS transistor. The principle of this electrostatic protection circuit 10 is as follows: when an electrostatic pulse appears on a power supply voltage end VDD and a VSS is grounded, an output end of the detection circuit outputs a first detection signal to the control circuit, and the first detection signal is a low-level signal; after the low-level signal passes through the control circuit including the transistor p1 and the transistor m1, a high level is outputted to the discharge transistor m2, the discharge transistor m2 is turned on and discharges electrostatic charges, and a time available for discharging electrostatic charges is determined by the product of the resistance r1 and the capacitance c1 of the detection circuit. This electrostatic protection circuit 10 requires a large Resistance Capacitance (RC) constant, so the capacitor c1 may be a large capacitor and the resistor r1 may be a large resistor. The large capacitor and large resistor could occupy a relatively large area in the chip, thus affecting the integration of chips. Also, the manufacturing process of semiconductor is becoming more and more advanced, and an Oxide layer is becoming thinner and thinner, so the large capacitor may cause serious leakage.

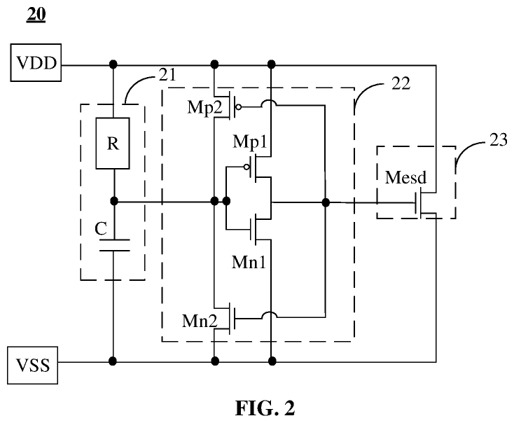

In some examples, an electrostatic protection circuit 20 as shown in FIG. 2 may be employed. The electrostatic protection circuit 20 includes a detection circuit 21, a control circuit 22 and a discharge transistor 23. The detection circuit 21 includes a resistor R and a capacitor C. The control circuit 22 includes a PMOS transistor Mp1, a PMOS transistor Mp2, an NMOS transistor Mn1 and an NMOS transistor Mn2. The discharge transistor 23 may be an NMOS transistor. The principle of the electrostatic protection circuit 20 is as follows: when an electrostatic pulse appears on a power supply voltage end VDD and a VSS is grounded, an output end of the detection circuit 21 outputs a first detection signal to the control circuit 22, and the first detection signal is a low-level signal. After the first detection signal passes through the PMOS transistor Mp1 and the NMOS transistor Mn1, an output end of the control circuit 22 inputs a high level to an input end of the discharge transistor 23, that is, a gate of the discharge transistor 23. The discharge transistor 23 may be an NMOS transistor Mesd, which is turned on when the gate voltage is at the high level, and the electrostatic pulse is discharged from the VDD end to the VSS end via the discharge transistor 23.

The control circuit 22 also includes a PMOS transistor Mp2 and an NMOS transistor Mn2. A gate of the PMOS transistor Mp2 and a gate of the NMOS transistor Mn2 are connected to the output end of the control circuit 22. Therefore, when the control circuit 22 outputs the high voltage, the NMOS transistor Mn2 is turned on when the gate voltage is at the high level. The NMOS transistor Mn2 may pull the input end voltage of the control circuit down to the low voltage, and pull the input end of the discharge transistor 23 to the high voltage, thus extending the turn-on time of the discharge transistor 23, so that the electrostatic pulse can be effectively discharged. However, this may result in the discharge transistor 23 not being turned off in time, so that it cannot return to normal operation.

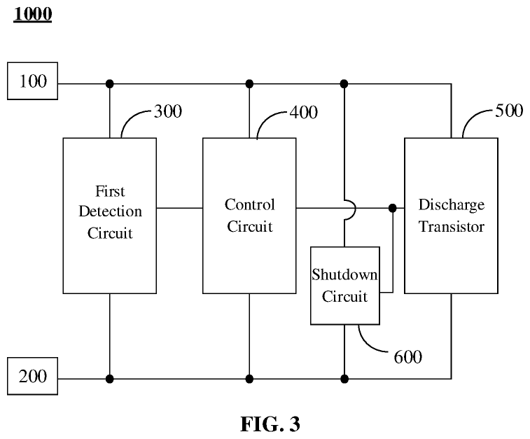

As shown in FIG. 3, an embodiment of the present disclosure provides an electrostatic protection circuit, and an electrostatic protection circuit 1000 is connected to a first voltage end 100 and a second voltage end 200. The electrostatic protection circuit 1000 includes a first detection circuit 300.

The first detection circuit 300 is connected between the first voltage end 100 and the second voltage end 200. The first detection circuit 300 is used to output a first detection signal within a first preset duration T1 after an electrostatic charge appears on the first voltage end 100, or output a second detection signal after the first preset duration T1 after the electrostatic charge appears on the first voltage end.

In some embodiments, the first voltage end 100 may be a power supply end VDD, and the second voltage end 200 may be a grounded end VSS.

The first detection circuit 300 has at least one output end for outputting at least two detection signals. Two detection signals may be the first detection signal and the second detection signal. The first detection circuit 300 may output the first detection signal within the first preset duration after an electrostatic charge appears on the power supply end VDD, and the first detection circuit 300 may output the second detection signal after the first preset duration after the electrostatic charge appears on the power supply end VDD.

In some embodiments, the first detection signal may be a high-level signal represented by binary data “1”, and the second detection signal may be a low-level signal represented by binary data “0”. In some embodiments, the first detection signal may be a low-level signal represented by binary data “0”, and the second detection signal may be a high-level signal represented by binary data “1”.

The electrostatic protection circuit 1000 may also include a control circuit 400, which is connected between the first voltage end 100 and the second voltage end 200. An input end of the control circuit 400 is connected to the output end of the first detection circuit 300. The control circuit 400 is used to output a first level if the first detection signal is received, or output a second level if the second detection signal is received.

The control circuit 400 includes at least one input end and at least one output end. One input end of the control circuit 400 is connected to the output end of the first detection circuit 300. That is, the signal inputted by the control circuit 400 is provided by the output end of the first detection circuit 300.

In some embodiments, the output end of the first detection circuit 300 may output the first detection signal within the first preset duration T1 after the electrostatic charge appears on the power supply end VDD, the first detection signal is inputted into the input end of the control circuit 400, and the control circuit 400 outputs a first level accordingly. The first level is used to turn on the discharge transistor 500 to discharge electrostatic charges. The first level may be either a high level or a low level, which is not limited here. In some embodiments, the output end of the first detection circuit 300 may output the second detection signal after the first preset duration after the electrostatic charge appears on the power supply end VDD, the second detection signal is inputted into the input end of the control circuit 400, and the control circuit 400 outputs the second level accordingly. The second level is used to turn off the discharge transistor 500. The second level may be either a high level or a low level, which is not limited here.

The electrostatic protection circuit 1000 may also include a discharge transistor 500, which is connected between the first voltage end 100 and the second voltage end 200. A control end of the discharge transistor 500 is connected to the output end of the control circuit 400. The discharge transistor 500 is switched to a turn-on state when the control end of the discharge transistor 500 is at the first level, so as to discharge the electrostatic charges to the second voltage end 200. The discharge transistor 500 is switched to a turn-off state when the control end of the discharge transistor 500 is at the second level.

This discharge transistor 500 may be either an NMOS transistor or a PMOS transistor. When the discharge transistor 500 is an asymmetric NMOS transistor, its first end (the end connected to the power supply end VDD) is a drain, and the drain has no lightly doped drain region (LDD structure), so as to reduce the conduction impedance of the discharge transistor 500 and improve the electrostatic charges discharge capacity of the discharge transistor 500. When the discharge transistor 500 is the asymmetric NMOS transistor, in order to further reduce the conduction impedance of the discharge transistor 500, the doping concentration in the drain region may be further increased so that the drain doping concentration is greater than the source doping concentration. Also, the area of the drain region can be further increased so that the drain area greater than the source area.

The control end of the discharge transistor 500 is connected to the output end of the control circuit, That is, the control circuit can control the state of the discharge transistor 500. The discharge transistor 500 at least includes two states including a turn-on state and a turn-off state.

In some embodiments, within the first preset duration after an electrostatic charge appears on the power supply end VDD, the output end of the first detection circuit may output the first detection signal, the first detection signal is inputted into the input end of the control circuit, and the control circuit outputs the first level accordingly. The first level may be either a high level or a low level, which is not limited here.

When the first level is the high level and the discharge transistor is an NMOS transistor, the discharge transistor is switched to the turn-on state when the control end of the discharge transistor is at the first level.

In some embodiments, the output end of the first detection circuit may output the second detection signal after the first preset duration after the electrostatic charge appears on the power supply end VDD, the second detection signal is inputted into the input end of the control circuit, and the control circuit outputs the second level accordingly. The second level may be either a high level or a low level, which is not limited here.

When the second level is the low level and the discharge transistor 500 is the NMOS transistor, the discharge transistor 500 is switched to the turn-off state when the control end of the discharge transistor 500 is at the second level.

The electrostatic protection circuit 1000 also includes a shutdown circuit 600, which is connected between the first voltage end 100 and the second voltage end 200. An output end of the shutdown circuit 600 is connected to the control end of the discharge transistor 500. The shutdown circuit 600 is used to output a control signal after a second preset duration after the electrostatic charge appears on the first voltage end 100. The control signal is used to turn off the discharge transistor 500.

The second preset duration is longer than or equal to the first preset duration.

The output end of the shutdown circuit 600 is connected to the control end of the discharge transistor 500. That is, the control end of the discharge transistor 500 is controlled not only by the output end of the control circuit 400, but also by the output end of the shutdown circuit 600. In this way, when the control circuit 400 cannot output a signal for turning off the discharge transistor 500 within a preset duration, the shutdown circuit 600 may be used to turn off the discharge transistor 500.

The shutdown circuit 600 may be one or more. Each shutdown circuit 600 may output a control signal after a certain period of time, to turn off the discharge transistor 500. For example, a first shutdown circuit may output a control signal to the discharge transistor 500 after a time T2, and the second shutdown circuit may output another control signal to the discharge transistor 500 after a time T3, and so on.

In one embodiment, one shutdown circuit 600 may be used, and this shutdown circuit 600 is used to output the control signal to the discharge transistor 500 for turning off the discharge transistor 500 after the second preset duration after an electrostatic charge appears on the power supply end VDD.

In some embodiments, the second preset duration may be longer than the first preset duration, so that the discharge transistor 500 may be turned off after the discharge transistor 500 completely discharges the electrostatic charges.

If the shutdown circuit 600 is not disposed in the electrostatic protection circuit 1000, when ESD occurs, there may be a problem that a latch-up may be occurred due to the discharge transistor 500 not being able to be turned off, or there may be a problem that the discharge transistor 500 needs a longer time to be turned off automatically after discharging static electricity. The above problems may affect the chip performance.

By providing at least one shutdown circuit 600, at least one way of turning off the discharge transistor 500 may be correspondingly added, so that the discharge transistor 500 may be turned off smoothly after discharging charges, the occurrence of the latch-up is reduced, and the performance of the chip is improved.

The shutdown circuit 600 is enabled after the second preset duration and the second preset duration is longer than or equal to the first preset duration. It may be appreciated that the first preset duration may be a period of time for the discharge transistor 500 to discharge electrostatic charges. If the second preset duration is shorter than the first preset duration, the discharge transistor 500 may be turned off before the discharge transistor 500 discharges all electrostatic charges, the electrostatic charges thus cannot be discharged completely. In the embodiments of the present disclosure, the second preset duration is longer than or equal to the first preset duration, so the discharge transistor 500 can be turned off until the electrostatic charges is discharged completely.

As shown in FIG. 3, when an electrostatic pulse appears on the power supply line VDD and the VSS power supply line is grounded, the output end of the detection circuit outputs a first detection signal to the input end of the control circuit 400 within a first preset duration T1, and the first detection signal may be a low-level signal. After the low level is inputted into the control circuit, a high level is outputted. The discharge transistor 500 may be an NMOS transistor which is turned on and discharges electrostatic charges with the high level inputted by the control circuit 400.

After the second preset duration T2, the shutdown circuit 600 is turned on. The shutdown circuit 600 inputs the low level to the control end of the discharge transistor 500, so that the discharge transistor 500 is turned off.

In one aspect, the electrostatic protection circuit 1000 proposed in the embodiments of the present disclosure can play the role of electrostatic protection when ESD occurs. In another aspect, according to the embodiments of the present disclosure, by providing an additional shutdown circuit 600, the problem that the discharge transistor 500 in the electrostatic protection circuit 1000 cannot be completely turned off within a preset duration can be solved, thus avoiding the occurrence of latch-up. In still another aspect, the electrostatic protection circuit 1000 proposed in the embodiments of the present disclosure may use a smaller resistor R and a smaller capacitor C, which may reduce the layout area of the electrostatic protection circuit 1000 and reduce the leakage caused by large capacitor C.

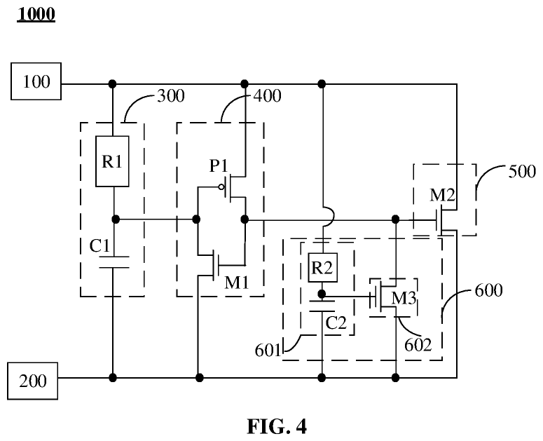

In some embodiments, as shown in FIG. 4, the shutdown circuit 600 includes a second detection circuit 601 and a shutdown transistor 602. The second detection circuit 601 is connected between the first voltage end 100 and the second voltage end 200. The second detection circuit 601 outputs a third detection signal within the second preset duration after an electrostatic charge appears on the first voltage end 100, or outputs a fourth detection signal after the second preset duration after the electrostatic charge appears on the first voltage end 100.

A first end of the shutdown transistor 602 is connected to the second voltage end 200, a second end of the shutdown transistor 602 is connected to the control end of the discharge transistor 500, and a control end of the shutdown transistor 602 is connected to the output end of the second detection circuit 601. The shutdown transistor 602 outputs a control signal after the second preset duration after the electrostatic charge appears on the first voltage end 100.

The shutdown circuit 600 at least includes the second detection circuit 601 and the shutdown transistor 602. The second detection circuit 601 may use a circuit composed of elements with the same type as that of the first detection circuit 300. However, the parameters of the elements used by the first detection circuit 300 may be different from the parameters of the elements used by the second detection circuit 601.

The first level outputted by the control circuit 400 to the discharge transistor 500 within the first preset duration is used to control the discharge transistor 500 to be turned on. The control signal outputted by the shutdown transistor 602 to the discharge transistor 500 after the second preset duration is used to control the discharge transistor 500 to be turned off.

It may be appreciated that when the first level is the high level, the level of the control signal may be the low level; and when the first level is the low level, the level of the control signal may be the high level.

The shutdown transistor 602 may be the same transistor as the discharge transistor 500 or may be a different transistor than the discharge transistor 500.

The second detection circuit 601 of the shutdown circuit 600 is used to control the time for outputting the control signal to the discharge transistor 500. By adjusting the parameters of the elements in the second detection circuit 601, a reasonable second preset duration may be obtained.

The shutdown transistor 602 of the shutdown circuit 600 is used to input a control signal, which may control the discharge transistor 500 to be turned off, to the discharge transistor 500 after the second preset duration.

In some embodiments, within the second preset duration after an electrostatic charge appears on the first voltage end, the output end of the second detection circuit outputs a third detection signal to the control end of the shutdown transistor so that the shutdown transistor is in the turn-off state.

After the second preset duration after an electrostatic charge appears on the first voltage end, the output end of the second detection circuit outputs a fourth detection signal to the control end of the shutdown transistor, so that the shutdown transistor is in the turn-on state and outputs the control signal to the control end of the discharge transistor.

Within the second preset duration, since the shutdown is not required to be performed by the shutdown transistor, the shutdown transistor may be in the turn-off state at this time, that is, the shutdown transistor does not output any signal to the input end of the discharge transistor. In some embodiments, the shutdown transistor may output a signal to the discharge transistor within the second preset duration so that the discharge transistor is turned on, and the level of this signal is the same as the first level.

It may be appreciated that the third detection signal and the fourth detection signal may be opposite signals. That is, when the third detection signal is at the high level, the fourth detection signal is at the low level. When the third detection signal is at the low level, the fourth detection signal is at the high level.

In some embodiments, as shown in FIG. 4, the second detection circuit 601 includes a second detection resistor R2 and a second detection capacitor C2.

The second detection resistor R2 is connected to the first voltage end 100.

The second detection capacitor C2 is connected between the second detection resistor R2 and the second voltage end 200. The end of the second detection resistor R2 that is connected to the second detection capacitor C2 is the output end of the second detection circuit 601.

The second detection circuit 601 may include at least one unit in which a second detection capacitor C2 and a second detection resistor R2 connected in series.

The second preset duration is determined by the product of the capacitance value of the second detection capacitor C2 and the resistance value of the second detection resistor R2. Therefore, the product of the capacitance value of the second detection capacitor C2 and the resistance value of the second detection resistor R2 can be less than or equal to the first preset duration, and the first preset duration may be a period of time for the discharge transistor 500 to discharge electrostatic charges.

If the second preset duration is required to be increased, it can be achieved by increasing the capacitance value of the second detection capacitor C2 and/or increasing the resistance value of the second detection resistor. If the second preset duration is required to be reduced, it can be achieved by reducing the capacitance value of the second detection capacitor C2 and/or reducing the resistance value of the second detection resistor.

In some embodiments, the second detection resistor R2 includes a polysilicon resistor or a doped area resistor.

The second detection resistor R2 may be integrated into the circuit by using a CMOS process. The polysilicon resistor is made of light doped polysilicon, and the resistance value of the polysilicon resistor can be adjusted by the light doped concentration. Therefore, the polysilicon resistor has the advantages of wide resistance value, adjustable range and small area. That is, the second preset duration can be correspondingly adjusted by adjusting the light doping concentration of the polysilicon resistor.

In some embodiments, the second detection capacitor C2 includes a MIM capacitor, a MOS capacitor, and a MOM capacitor. The second detection capacitor C2 may be integrated into the circuit by using a CMOS process.

MOS capacitors include NMOS capacitors and PMOS capacitors. For MOS capacitors, the gate oxide layer between the gate layer and the channel may be used as an insulating layer, the gate layer may be used as an upper plate, and a lower plate may be formed by shorting the three ends of the source, drain and the substrate. The capacitance value of the MOS capacitor may change with the control voltage, so the capacitance value can be adjusted, and an adjustable second preset duration can be obtained. The MIM capacitors can be formed by utilizing different layers of metals and the dielectric between them. The MIM capacitors can be formed without additional mask. Therefore, the implementation method is simple. The capacitance value of the MIM capacitor is relatively accurate, and the capacitance value will not change with the bias voltage. When it is required to design a fixed second preset duration, the MIM capacitors can be used. The MOM capacitors can be constructed by utilizing the insertion structure of the same layer of metal. Under the condition of the same area, the capacitance value of the MIM capacitor is less than the capacitance value of the MOM capacitor. When the capacitance value is fixed and it is expected to use less capacitor area, the MOM capacitors can be selected.

In some embodiments, as shown in FIG. 4, the first detection circuit 300 includes a first detection resistor R1 and a first detection capacitor C1. The first detection resistor R1 is connected to the first voltage end 100.

The first detection capacitor C1 is connected between the first detection resistor R1 and the second voltage end 200.

The end of the first detection resistor R1 that is connected to the first detection capacitor C1 is the output end of the first detection circuit 300.

It may be appreciated that the first detection circuit 300 may also include at least one unit in which a first detection capacitor C1 and a first detection resistor R1 are connected in series. The capacitance value of the first detection capacitor C1 and the capacitance value of the second detection capacitor C2 may be the same or different. The resistance value of the first detection resistor R1 and the resistance value of the second detection resistor R2 may be the same or different. However, a first time constant for the first detection resistor R1 and the first detection capacitor C1 may be less than or equal to a second time constant for the second detection resistor R2 and the second detection capacitor C2.

The first time constant is the first preset duration, and the second time constant is the second preset duration.

In some embodiments, the first time constant may be less than 40 ns, and the second time constant may be between 200 ns and 1 us.

In some embodiments, as shown in FIG. 4, the control circuit 400 includes a first control switch P1, which is connected between the first voltage end 100 and the control end of the discharge transistor 500. The output end of the first detection circuit 300 is connected to a control end of the first control switch P1.

In some embodiments, the control circuit 400 also includes a second control switch M1, which is connected between the output end of the first detection circuit 300 and the second voltage end 200. A control end of the second control switch M1 is connected to the control end of the discharge transistor 500.

In some embodiments, the first control switch P1 is a PMOS transistor. The first control switch P1 can reverse the input low level into the high level, so as to turn on the discharge transistor 500 so that the electrostatic charges can be released in time.

In some embodiments, the second control switch M1 is an NMOS transistor. The second control switch M1 can keep the voltage at the input end of the control circuit at a low voltage continuously to prevent it reversing into the high level. Therefore, the turn-on time period of the discharge transistor 500 may be extended so that the electrostatic charges can be released in time.

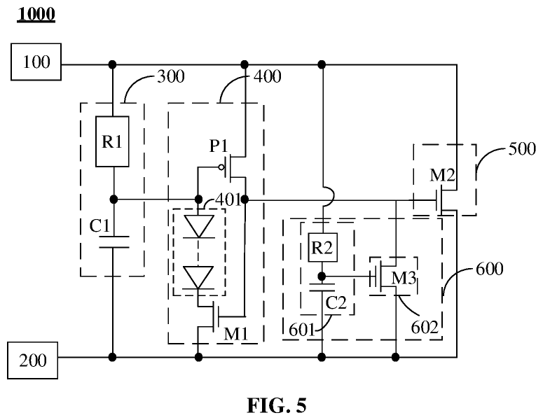

In some embodiments, as shown in FIG. 5, the control circuit 400 also includes at least one diode 401 connected in series between the control end of the first control switch P1 and a second end of the second control switch M1. The at least one diode 401 is used to single-guide the current from the control end of the first control switch P1 to the second end of the second control switch M1.

In some embodiments, there is at least one diode 401 between the control end of the first control switch P1 and the second control switch M1, for example, one diode 401 or a diode string composed of two or more diodes 401. This diode 401 may be a germanium diode (Ge transistor), a silicon diode (Si transistor) and a polysilicon diode, and the embodiments of the present disclosure are not limited thereto.

The at least one diode 401 may be used to further improve the capacity of resisting latch-up between the first control switch P1 and the second control switch M1. If the holding voltage between the first control switch P1 and the second control switch M1 is less than the normal operating voltage, the latch-up can be maintained, and thus a large current flows between the first voltage end 100 (for example, VDD) and the second voltage end 200 (for example, VSS) until the chip is burned. Therefore, to suppress the occurrence of latch-up, the holding voltage between the first control switch P1 and the second control switch M1 can be increased to be greater than the normal operating voltage. Adding at least one diode 401 here is equivalent to adding the voltage of at least one diode 401 on the basis of the original holding voltage, so as to increase the effective holding voltage and better prevent the occurrence of latch-up.

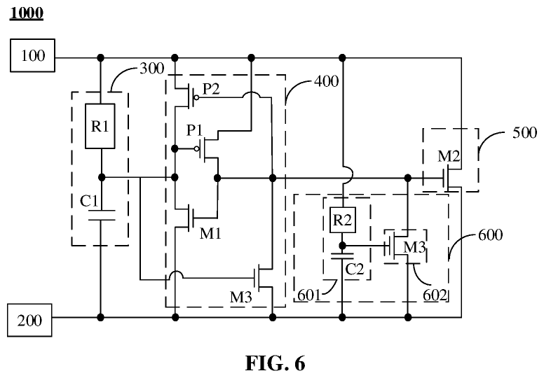

In some embodiments, as shown in FIG. 6, the control circuit 400 also includes a third control switch M3.

The control end of the third control switch is connected to the output end of the first detection circuit 300.

A first end of the third control switch M3 is connected to the control end of the discharge transistor 500.

A second end of the third control switch M3 is connected to the second voltage end 200.

In some embodiments, the control circuit 400 also includes a fourth control switch P2.

A control end of the fourth control switch P2 is connected to the control end of the discharge transistor 500.

A first end of the fourth control switch P2 is connected to the first voltage end 100.

A second end of the fourth control switch P2 is connected to the input end of the control circuit 400.

The third control switch M3 may be an NMOS transistor. The third control switch M3 may be turned on after a certain period of time after the discharge transistor 500 discharges electrostatic charges. The output end of the third control switch M3 is used to pull the voltage at the input end of the discharge transistor 500 down to a low voltage so as to shut down the discharge transistor 500.

The fourth control switch P2 may be a PMOS transistor. The control end of the fourth control switch P2 is connected to the output end of the control circuit 400. The first end of the fourth control switch P2 is connected to the first voltage end 100 (for example, VDD), and the second end of the fourth control switch P2 is connected to the input end of the control circuit 400. The fourth control switch P2 is used to accelerate the reverse of the voltage at the input end of the control circuit 400 from a low voltage to a high voltage in response to the second level outputted by the control circuit 400, so that the discharge transistor 500 can be quickly shut down through the third control switch M3 after completing the discharge of electrostatic charges.

When there is no ESD at the first voltage end 100, that is, when the stable value of normal operation is maintained, the third control switch M3 may be turned on, so that the voltage at the output end of the control circuit 400 is at the low voltage, and the fourth control switch P2 can further pull up or maintain the voltage at the input end of the control circuit 400 to or at the high voltage. In such a way, the capacity of the control circuit 400 to output the low voltage is stronger, which ensures that the discharge transistor 500 is shut down better, and thus reducing the leakage current from the first voltage end 100 (for example, VDD) to the second voltage end 200 (for example, VSS) during normal operation.

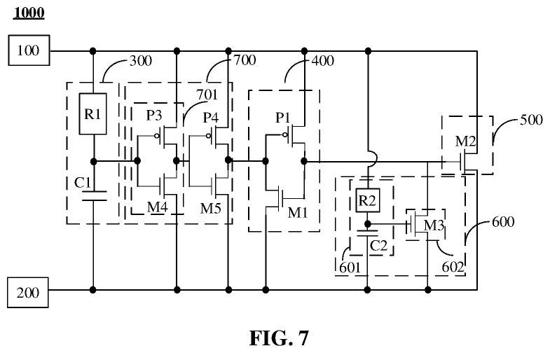

In some embodiments, as shown in FIG. 7, the electrostatic protection circuit 1000 also includes a delay circuit 700.

The delay circuit 700 includes a group of inverters. The group of inverters includes an even number of interconnected inverters 701.

The inverter group is connected between the first voltage end 100 and the second voltage end 200.

A first end of the group of inverters is connected to the output end of the first detection circuit 300. A second end of the group of inverters is connected to the input end of the control circuit 400.

In some embodiments, the inverter 701 includes a first inverting transistor P3 and a second inverting transistor M4.

A first end of the first inverting transistor P3 is connected to the first voltage end 100.

A first end of the second inverting transistor M4 is connected to the second voltage end 200.

A control end of the first inverting transistor P3 is connected to a control end of the second inverting transistor M4. A second end of the first inverting transistor P3 is connected to a second end of the second inverting transistor M4.

In some embodiments, an even number of inverters 701 can also be disposed between the first detection circuit 300 and the control circuit 400. The even number of inverters 701 are a group of inverters, and the even number of inverters 701 are connected in series with each other. Each inverter 701 may include a first inverter transistor P3 and a second inverter transistor M4. The input of the first inverting transistor P3 is connected to the output end of the first detection circuit 300, the output end of the first inverting transistor P3 is connected to the input end of the second inverting transistor M4, and the output end of the second inverting transistor M4 (or an inverter with an even number) is connected to the input end of the control circuit 400. The group of inverters can realize the input buffering function.

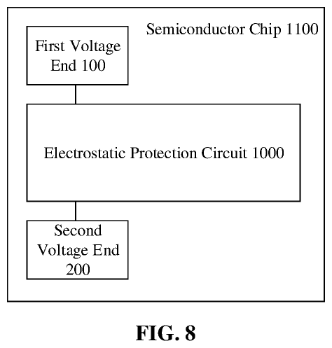

As shown in FIG. 8, the embodiments of the present disclosure also provide a semiconductor chip. The semiconductor chip 1100 includes a first voltage end 100, a second voltage end 200 and the electrostatic protection circuit 1000 described as any of the above embodiments.

Any electrostatic protection circuit 1000 according to the embodiments of the present disclosure may be used in the semiconductor chip 1100 or integrated circuit to provide electrostatic protection for the chip or integrated circuit.

On the one hand, the electrostatic protection circuit proposed in the embodiments of the present disclosure can play the role of electrostatic protection when ESD occurs; on the other hand, by setting an additional shutdown circuit, the embodiments of the present disclosure also solve the problem that it is difficult to turn off the discharge circuit in the electrostatic protection circuit within a preset duration, thereby reducing the occurrence of latch-up. In addition, the electrostatic protection circuit proposed in the embodiments of the present disclosure can use smaller resistor R and capacitor C, which can reduce the layout area of the electrostatic protection circuit and reduce the leakage caused by a large capacitor C.

It should be appreciated that “some embodiments”, “one embodiment” or “an embodiment” mentioned throughout the specification means that specific features, structures or characteristics related to implementation are included in at least one embodiment of the present disclosure. Therefore, “in one embodiment” or “in an embodiment” appearing throughout the specification may not necessarily refer to a same embodiment. Furthermore, these specific features, structures, or characteristics may be combined in one or more embodiments in any suitable manner. It should be appreciated that in various embodiments of the present disclosure, the size of the serial numbers of the above processes does not mean the order of execution, and the execution order of various processes should be determined by their functions and internal logic, without any restriction on the implementation process of the embodiments of the present disclosure. The serial numbers of the embodiments of the present disclosure are only for description and do not represent the advantages and disadvantages of the embodiments.

It should be noted that, the terms “including”, “comprising” or any other variant thereof herein are intended to cover non-exclusive inclusion, so that a process, method, article or device including a series of elements not only includes those elements, but also includes other elements not explicitly listed, or also includes elements inherent to such process, method, article or device. Without further restrictions, the element defined by the statement “including a . . . ” does not exclude the existence of an additional identical element in the process, method, article or device including the element.

The above is only the implementation mode of the present disclosure, but the protection scope of the present disclosure is not limited to this. Changes or replacements which can be easily thought of within the scope of the present disclosure by any person skilled in the art should be covered in the protection scope of the present disclosure. Therefore, the protection scope of the present disclosure shall comply with the protection scope of the claims.

### INDUSTRIAL APPLICABILITY

On the one hand, the electrostatic protection circuit proposed in the embodiments of the present disclosure can play the role of electrostatic protection when ESD occurs; on the other hand, the embodiments of the present disclosure also solve the problem that the discharge circuit in the electrostatic protection circuit is difficult to be shut down within a preset duration by depositing an additional shutdown circuit, thereby reducing the occurrence of latch-up. In addition, the electrostatic protection circuit proposed in the embodiments of the present disclosure can use smaller resistor R and capacitor C, which can reduce the layout area of the electrostatic protection circuit and reduce the leakage caused by large capacitor C.

What is claimed is:

1. An electrostatic protection circuit connected to a first voltage end and a second voltage end, comprising:
a first detection circuit connected between the first voltage end and the second voltage end, wherein the first detection circuit is configured to: output a first detection signal within a first preset duration after an electrostatic charge appears on the first voltage end, or output a second detection signal after the first preset duration after the electrostatic charge appears on the first voltage end;
a control circuit connected between the first voltage end and the second voltage end, wherein an input end of the control circuit is connected to an output end of the first detection circuit, and the control circuit is configured to: output a first level in a state that the first detection signal is received, or output a second level in a state of the second detection signal is received;
a discharge transistor connected between the first voltage end and the second voltage end, wherein a control end of the discharge transistor is connected to an output end of the control circuit, the discharge transistor is configured to be switched to a turn-on state when the control end of the discharge transistor is at the first level, so as to discharge the electrostatic charge to the second voltage end, and the discharge transistor is further configured to be switched to a turn-off state when the control end of the discharge transistor is at the second level; and
a shutdown circuit connected between the first voltage end and the second voltage end, wherein an output end of the shutdown circuit is connected to the control end of the discharge transistor, the shutdown circuit is configured to output a control signal after a second preset duration after the electrostatic charge appears on the first voltage end, and the control signal is used to turn off the discharge transistor,
wherein the second preset duration is greater than or equal to the first preset duration.

2. The electrostatic protection circuit of claim 1, wherein the shutdown circuit comprises:
a second detection circuit connected between the first voltage end and the second voltage end, wherein the second detection circuit is configured to: output a third detection signal within the second preset duration after the electrostatic charge appears on the first voltage end, or output a fourth detection signal after the second preset duration after the electrostatic charge appears on the first voltage end; and
a shutdown transistor, wherein a first end of the shutdown transistor is connected to the second voltage end, a second end of the shutdown transistor is connected to the control end of the discharge transistor, and a control end of the shutdown transistor is connected to the output end of the second detection circuit, and the shutdown transistor is configured to output the control signal after the second preset duration after the electrostatic charge appears on the first voltage end.

3. The electrostatic protection circuit of claim 2, wherein, within the second preset duration after the electrostatic charge appears on the first voltage end, the output end of the second detection circuit is configured to output the third detection signal to the control end of the shutdown transistor and the shutdown transistor is in a turn-off state, and
after the second preset duration after the electrostatic charge appears on the first voltage end, the output end of the second detection circuit is configured to output the fourth detection signal to the control end of the shutdown transistor, and the shutdown transistor is in a turn-on state to output the control signal to the control end of the discharge transistor.

4. The electrostatic protection circuit of claim 2, wherein the second detection circuit comprises:
a second detection resistor connected to the first voltage end; and
a second detection capacitor connected between the second detection resistor and the second voltage end, wherein one end of the second detection resistor connected to the second detection capacitor is the output end of the second detection circuit.

5. The electrostatic protection circuit of claim 4, wherein the second detection resistor comprises a polysilicon resistor or a doped area resistor.

6. The electrostatic protection circuit of claim 4, wherein the second detection capacitor comprises a Metal-Insulator-Metal (MIM) capacitor, \a Metal-Oxide-Semiconductor (MOS) capacitor or a Metal-Oxide-Metal (MOM) capacitor.

7. The electrostatic protection circuit of claim 1, wherein the first detection circuit comprises:
a first detection resistor connected to the first voltage end; and
a first detection capacitor connected between the first detection resistor and the second voltage end,
wherein one end of the first detection resistor connected to the first detection capacitor is the output end of the first detection circuit.

8. The electrostatic protection circuit of claim 1, wherein the control circuit comprises:
a first control switch connected between the first voltage end and the control end of the discharge transistor, wherein the output end of the first detection circuit is connected to a control end of the first control switch.

9. The electrostatic protection circuit of claim 8, wherein the control circuit further comprises:
a second control switch connected between the output end of the first detection circuit and the second voltage end, wherein a control end of the second control switch is connected to the control end of the discharge transistor.

10. The electrostatic protection circuit of claim 9, wherein the control circuit further comprises:
at least one diode connected in series between the control end of the first control switch and a second end of the second control switch, wherein the at least one diode is configured to single-guide current from the control end of the first control switch to the second end of the second control switch.

11. The electrostatic protection circuit of claim 9, wherein the control circuit further comprises:
a third control switch, wherein
a control end of the third control switch is connected to the output end of the first detection circuit,
a first end of the third control switch is connected to the control end of the discharge transistor, and
a second end of the third control switch is connected to the second voltage end.

12. The electrostatic protection circuit of claim 11, wherein the control circuit further comprises a fourth control switch, wherein
a control end of the fourth control switch is connected to the control end of the discharge transistor,
a first end of the fourth control switch is connected to the first voltage end, and
a second end of the fourth control switch is connected to the input end of the control circuit.

13. The electrostatic protection circuit of claim 1, wherein the electrostatic protection circuit further comprises a delay circuit, wherein
the delay circuit comprises a group of inverters which comprises an even number of interconnected inverters,
the group of inverters is connected between the first voltage end and the second voltage end, and
a first end of the group of inverters is connected to the output end of the first detection circuit and a second end of the group of inverters is connected to the input end of the control circuit.

14. The electrostatic protection circuit of claim 13, wherein each inverter comprises:
a first inverting transistor, wherein a first end of the first inverting transistor is connected to the first voltage end; and
a second inverting transistor, wherein a first end of the second inverting transistor is connected to the second voltage end,
where a control end of the first inverting transistor is connected to a control end of the second inverting transistor and a second end of the first inverting transistor is connected to a second end of the second inverting transistor.

15. A semiconductor chip, comprising:
a first voltage end, a second voltage end and an electrostatic protection circuit,
wherein the electrostatic protection circuit is connected to a first voltage end and a second voltage end, and the electrostatic protection circuit comprises:
a first detection circuit connected between the first voltage end and the second voltage end, wherein the first detection circuit is configured to: output a first detection signal within a first preset duration after an electrostatic charge appears on the first voltage end, or output a second detection signal after the first preset duration after the electrostatic charge appears on the first voltage end;
a control circuit connected between the first voltage end and the second voltage end, wherein an input end of the control circuit is connected to an output end of the first detection circuit, and the control circuit is configured to: output a first level in a state that the first detection signal is received, or output a second level in a state of the second detection signal is received;
a discharge transistor connected between the first voltage end and the second voltage end, wherein a control end of the discharge transistor is connected to an output end of the control circuit, the discharge transistor is configured to be switched to a turn-on state when the control end of the discharge transistor is at the first level, so as to discharge the electrostatic charge to the second voltage end, and the discharge transistor is further configured to be switched to a turn-off state when the control end of the discharge transistor is at the second level; and
a shutdown circuit connected between the first voltage end and the second voltage end, wherein an output end of the shutdown circuit is connected to the control end of the discharge transistor, the shutdown circuit is configured to output a control signal after a second preset duration after the electrostatic charge appears on the first voltage end, and the control signal is used to turn off the discharge transistor,
wherein the second preset duration is greater than or equal to the first preset duration.

16. The semiconductor chip of claim 15, wherein the shutdown circuit comprises:
a second detection circuit connected between the first voltage end and the second voltage end, wherein the second detection circuit is configured to: output a third detection signal within the second preset duration after the electrostatic charge appears on the first voltage end, or output a fourth detection signal after the second preset duration after the electrostatic charge appears on the first voltage end; and
a shutdown transistor, wherein a first end of the shutdown transistor is connected to the second voltage end, a second end of the shutdown transistor is connected to the control end of the discharge transistor, and a control end of the shutdown transistor is connected to the output end of the second detection circuit, and the shutdown transistor is configured to output the control signal after the second preset duration after the electrostatic charge appears on the first voltage end.

17. The semiconductor chip of claim 16, wherein, within the second preset duration after the electrostatic charge appears on the first voltage end, the output end of the second detection circuit is configured to output the third detection signal to the control end of the shutdown transistor and the shutdown transistor is in a turn-off state, and
after the second preset duration after the electrostatic charge appears on the first voltage end, the output end of the second detection circuit is configured to output the fourth detection signal to the control end of the shutdown transistor, and the shutdown transistor is in a turn-on state to output the control signal to the control end of the discharge transistor.

18. The semiconductor chip of claim 16, wherein the second detection circuit comprises:
a second detection resistor connected to the first voltage end; and
a second detection capacitor connected between the second detection resistor and the second voltage end, wherein one end of the second detection resistor connected to the second detection capacitor is the output end of the second detection circuit.

19. The semiconductor chip of claim 15, wherein the first detection circuit comprises:
a first detection resistor connected to the first voltage end; and
a first detection capacitor connected between the first detection resistor and the second voltage end,
wherein one end of the first detection resistor connected to the first detection capacitor is the output end of the first detection circuit.

20. The semiconductor chip of claim 15, wherein the control circuit comprises:
a first control switch connected between the first voltage end and the control end of the discharge transistor, wherein the output end of the first detection circuit is connected to a control end of the first control switch.
